(19) United States
(12) Patent Application Publication
(10) Pub. No.: US 2026/0040712 A1
(43) Pub. Date: Feb. 5, 2026

(54) PHOTOELECTRIC CONVERSION APPARATUS, DEVICE, AND METHOD FOR MANUFACTURING PHOTOELECTRIC CONVERSION APPARATUS

(71) Applicant: CANON KABUSHIKI KAISHA, Tokyo (JP)

(72) Inventors: TAKAFUMI MIKI, Kanagawa (JP); YOSHIYUKI NAKAGAWA, Kanagawa (JP); YUSUKE ONUKI, Kanagawa (JP); TSUTOMU TANGE, Kanagawa (JP)

(21) Appl. No.: 19/282,589

(22) Filed: Jul. 28, 2025

(30) Foreign Application Priority Data
Jul. 30, 2024 (JP) 2024-123118

(51) Int. Cl. H10F 39/00; H01L 23/00

(52) U.S. Cl. CPC H10F 39/809; H01L 24/08; H01L 24/80; H10F 39/018; H10F 39/811; H01L 2224/08145; H01L 2224/80895; H01L 2224/80896

(57) ABSTRACT

According to an aspect of the disclosure of this specification, a photoelectric conversion apparatus includes a first semiconductor substrate, a first wiring structure, a second wiring structure, and a second semiconductor substrate, wherein the first semiconductor substrate includes a protection element and a plurality of pixels arranged in a row direction and a column direction, wherein a signal is supplied from the second semiconductor substrate to a gate electrode of a transistor, wherein the first wiring structure includes a first wiring line extending in at least one of the row direction and the column direction in such a manner as to overlap two or more pixels in a planar view, the signal passing through the first wiring line, wherein the first wiring line and the protection element are connected, and wherein a reverse bias voltage is applied to a diode constituting the protection element.

### BACKGROUND

### Field of the Technology

The present disclosure relates to a photoelectric conversion apparatus, a device, and a method for manufacturing a photoelectric conversion apparatus.

### Description of the Related Art

In recent years, a complementary metal-oxide semiconductor (CMOS) image sensor suitable for high-speed readout has been widely used in a photoelectric conversion apparatus such as a digital still camera or a digital camera. For example, Japanese Patent Application Laid-Open No. 2021-125491 discusses a photoelectric conversion apparatus in which a first substrate including a first semiconductor substrate and a first wiring structure, and a second substrate including a second wiring structure and a second semiconductor substrate are stacked. Japanese Patent Application Laid-Open No. 2021-125491 discusses that a circuit arranged on the first substrate and a circuit arranged on the second substrate are connected via a metal bonding portion. Japanese Patent Application Laid-Open No. 2021-125491 also discusses that a circuit connected to the metal bonding portion is protected from large current generated in a process of bonding the first substrate and the second substrate, by arranging a protection element on at least one of the first substrate and the second substrate, and electrically connecting the metal bonding portion and the protection element.

During a process of forming a first member, a gate insulator film of a transistor included in the first substrate deteriorates, and potential fails to be supplied to the transistor from the second substrate, whereby malfunction or manufacturing failure of the photoelectric conversion apparatus might occur. Nevertheless, such cases are not considered in Japanese Patent Application Laid-Open No. 2021-125491.

### SUMMARY

According to an exemplary embodiment of the present disclosure, it is possible to reduce deterioration of a gate insulator film, and reduce malfunction or manufacturing failure of a photoelectric conversion apparatus.

According to an aspect of the disclosure of this specification, there is provided a photoelectric conversion apparatus including a first semiconductor substrate including a pixel including a photoelectric conversion element and a transistor, a first wiring structure, a second wiring structure, and a second semiconductor substrate configured to generate a signal to be applied to a gate electrode of the transistor and supply the signal to the transistor, the first semiconductor substrate, the first wiring structure, the second wiring structure, and the second semiconductor substrate being stacked in this order, wherein the first semiconductor substrate includes a protection element and a plurality of the pixels arranged in a row direction and a column direction, wherein the signal is supplied from the second semiconductor substrate to the gate electrode of the transistor, wherein the first wiring structure includes a first wiring line extending in at least one of the row direction and the column direction in such a manner as to overlap two or more pixels in a planar view, the signal passing through the first wiring line, and wherein the first wiring line and the protection element are connected.

According to another aspect of the disclosure of this specification, there is provided a photoelectric conversion apparatus including a first semiconductor substrate including a pixel including a photoelectric conversion element and a transistor, the first semiconductor substrate being stacked on a second semiconductor substrate, the first semiconductor substrate including a protection element and a plurality of the pixels arranged in a row direction and a column direction, and a first wiring structure including a first wiring line extending in at least one of the row direction and the column direction in such a manner as to overlap two or more pixels in a planar view, a signal to be applied to a gate electrode of the transistor passing through the first wiring line, wherein the first wiring line and the protection element are connected, and wherein the first wiring line and the gate electrode of the transistor are connected.

According to yet another aspect of the disclosure of this specification, there is provided a manufacturing method of a photoelectric conversion apparatus including preparing a first substrate in which a first semiconductor substrate and a first wiring structure are stacked in this order, preparing a second substrate in which a second wiring structure and a second semiconductor substrate are stacked in this order, and bonding the first substrate and the second substrate in such a manner that the first wiring structure and the second wiring structure face each other, wherein the preparing the first substrate includes preparing a first semiconductor substrate including a protection element, and a plurality of pixels each including a photoelectric conversion element and a transistor that are arranged in a row direction and a column direction, and forming a first wiring line that is included in the first wiring structure and extends in at least one of the row direction and the column direction, in such a manner that the protection element and the first wiring line, and a gate electrode of the transistor and the first wiring line are connected.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic chip diagram illustrating a photoelectric conversion apparatus according to a first exemplary embodiment.

FIG. 2 is a circuit diagram illustrating the photoelectric conversion apparatus according to the first exemplary embodiment.

FIG. 3 is a schematic plan view illustrating a pixel of the photoelectric conversion apparatus according to the first exemplary embodiment.

FIGS. 4A and 4B are a schematic top view and a schematic cross-sectional view illustrating the photoelectric conversion apparatus according to the first exemplary embodiment.

FIG. 5 is a schematic top view illustrating another example of the photoelectric conversion apparatus according to the first exemplary embodiment.

FIG. 6 is a schematic top view illustrating another example of the photoelectric conversion apparatus according to the first exemplary embodiment.

FIG. 7 is a top view illustrating a pad and a pixel region of the photoelectric conversion apparatus according to the first exemplary embodiment.

FIG. 8 is a schematic cross-sectional view illustrating the photoelectric conversion apparatus according to the first exemplary embodiment.

FIGS. 9A and 9B are circuit diagrams of a protection element of the photoelectric conversion apparatus according to the first exemplary embodiment.

FIG. 10 is a schematic cross-sectional view illustrating a photoelectric conversion apparatus according to a second exemplary embodiment.

FIG. 11 is a schematic cross-sectional view illustrating a photoelectric conversion apparatus according to a third exemplary embodiment.

FIGS. 12A to 12E are process flow diagrams illustrating the photoelectric conversion apparatus according to the third exemplary embodiment.

FIGS. 13A to 13C are schematic diagrams illustrating a device according to a fourth exemplary embodiment.

### DESCRIPTION OF THE EMBODIMENTS

Hereinafter, exemplary embodiments will be described with reference to the drawings. The following exemplary embodiments are not intended to limit the invention set forth in the appended claims. A plurality of features are described in the exemplary embodiments, but not all the plurality of features are always essential to the invention. In addition, the plurality of features may be arbitrarily combined. Furthermore, in the accompanying drawings, the same or similar components are assigned the same reference numerals, and the redundant description will be omitted. In each exemplary embodiment to be described below, a sensor for image capturing (imaging apparatus) will be mainly described as an example of a photoelectric conversion apparatus. Nevertheless, the photoelectric conversion apparatus in each exemplary embodiment is not limited to the sensor for image capturing, and each exemplary embodiment can be applied to another example of the photoelectric conversion apparatus. Examples of the photoelectric conversion apparatus include a distance measurement apparatus (apparatus of distance measurement that uses focus detection or Time Of Flight (TOF)), and a photometric apparatus (apparatus of measurement of an incident light amount).

In this specification, terms (e.g., “up”, “down”, “right”, “left”, and other terms including these terms) indicating specific directions and positions are used as necessary. These terms are used to facilitate the understanding of the exemplary embodiment to be described with reference to the drawings. The technical scope of the present invention is not limited by the meanings of these terms.

In this specification, a “plane” refers to a surface in a direction parallel to a principal surface of a substrate. The principal surface of the substrate can be a light incidence surface of the substrate that includes a photoelectric conversion element, a surface on which a plurality of analog-to-digital converters (ADCs) are repeatedly arranged, or a bonded surface of a substrate and a substrate in a stack-type photoelectric conversion apparatus. A “planar view” refers to viewing from a direction vertical to the principal surface of the substrate. Furthermore, a “cross-section” refers to a surface in a direction vertical to a light incidence surface of a semiconductor layer. In addition, a cross-sectional view refers to viewing a direction parallel to the principal surface of the substrate.

In this specification, connection between elements of a circuit will be sometimes described. In this case, even in a case where another element is interposed between elements to be observed, the elements to be observed will be regarded as being connected, unless otherwise stated. For example, it is assumed that an element A is connected to one node of a capacitive element C having a plurality of nodes, and an element B is connected to the other node. Even in such a case, the elements A and B are regarded as being connected, unless otherwise stated.

In this specification, in a case where it is described that “a member A and a member B are electrically connected”, the case is not limited to a case where the member A and the member B are directly connected. For example, even if another member C is connected between the member A and the member B, it is sufficient that the member A and the member B are electrically connected.

A metal member such as a wire or a pad to be described in this specification may be a metal single body of certain one element, or may be a mixture (alloy). For example, a wire to be described as a copper wire may be a copper single body, or may have a configuration mainly containing copper and further containing other components. In addition, for example, a pad to be connected to an external terminal may be an aluminum single body, or may may have a configuration mainly containing aluminum and further containing other components. The copper wire and the aluminum pad described here are examples, and can be changed to various types of metal. In addition, the wire and the pad described here are examples of metal members to be used in a photoelectric conversion apparatus, and can also be applied to other metal members.

In the following description, charges to be accumulated by a photoelectric conversion unit in a pixel are electrons. In addition, all transistors included in the pixel are N-channel metal-oxide semiconductor (MOS) transistors (hereinafter, abbreviated as NMOS transistors). Nevertheless, charges to be accumulated by a photoelectric conversion unit may be holes. In this case, transistors of the pixel may be P-channel MOS transistors (hereinafter, abbreviated as PMOS transistors). That is, the conductivity type of transistors can be appropriately changed in accordance with the polarity of charges to be regarded as signals.

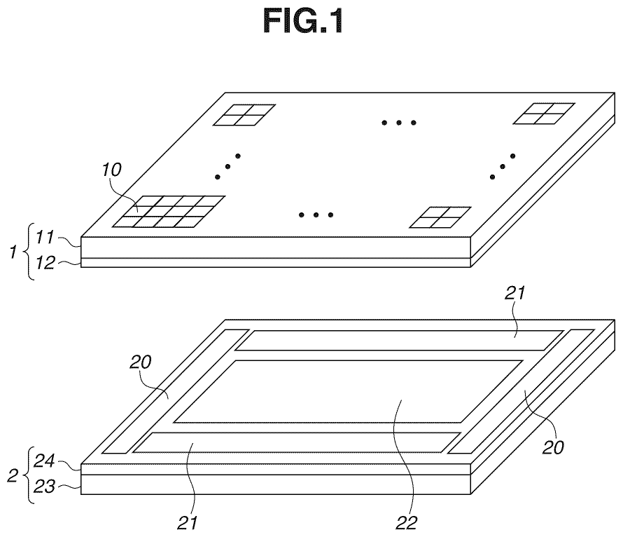

A photoelectric conversion apparatus according to a first exemplary embodiment of the present disclosure will be described with reference to FIGS. 1 to 9A and 9B.

FIG. 1 is a schematic diagram of a photoelectric conversion apparatus according to the present exemplary embodiment. FIG. 1 illustrates a photoelectric conversion apparatus serving as a stack-type back-illuminated imaging apparatus. All or part of the stack-type back-illuminated imaging apparatus corresponds to a semiconductor device integrated circuit (IC) being a stacked member of a first substrate 1 and a second substrate 2. In the case of part of the stack-type back-illuminated imaging apparatus that corresponds to a stacked member of the first substrate 1 and the second substrate 2, the stack-type back-illuminated imaging apparatus includes a photoelectric conversion apparatus in which three or more substrates are stacked, such as a photoelectric conversion apparatus in which a third substrate including a semiconductor element is stacked on the stacked member of the first substrate 1 and the second substrate 2, for example.

The photoelectric conversion apparatus according to the present exemplary embodiment is a stacked member of the first substrate 1 and the second substrate 2. The first substrate 1 includes a plurality of pixels 10 arranged in a matrix over a plurality of rows and a plurality of columns. On the second substrate 2, a row scanning circuit 20 and a column scanning circuit 21 for driving the pixels 10, and a signal processing circuit 22 that processes signals from the pixels 10 are arranged.

The first substrate 1 includes a semiconductor layer 11 (first semiconductor substrate) in which a plurality of semiconductor elements constituting the plurality of pixels 10 are provided, and a wiring structure 12 (first wiring structure) including M-layered wiring layers electrically connected to the plurality of pixels 10. The second substrate 2 includes a semiconductor layer 23 (second semiconductor substrate) in which a plurality of semiconductor elements constituting a plurality of electric circuits such as the row scanning circuit 20, the column scanning circuit 21, and the signal processing circuit 22 are provided, and a wiring structure 24 (second wiring structure) including N-layered wiring layers constituting a plurality of electric circuits. The wiring structure 12 is arranged between the semiconductor layer 11 and the semiconductor layer 23, and the wiring structure 24 is arranged between the wiring structure 12 and the semiconductor layer 23.

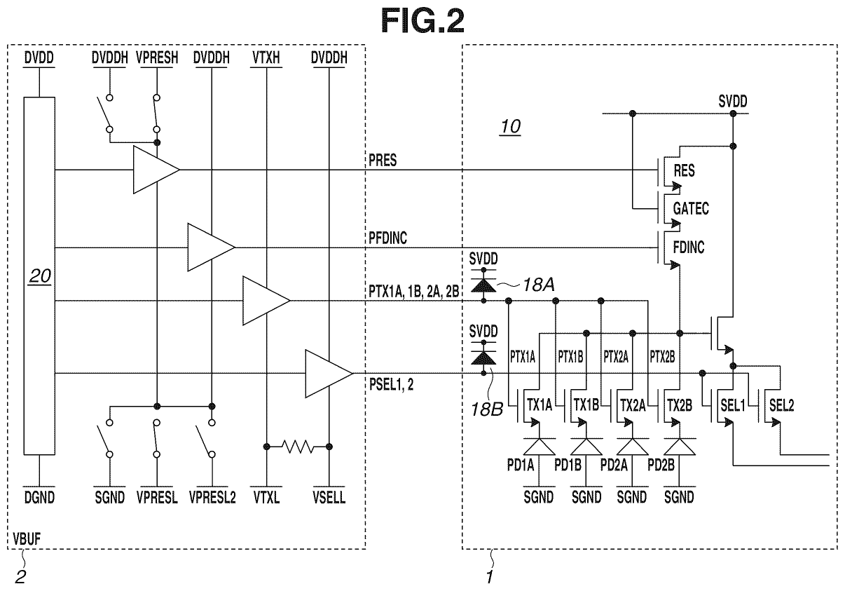

FIG. 2 is a circuit diagram illustrating the photoelectric conversion apparatus

according to the present exemplary embodiment.

As illustrated in FIG. 2, the first substrate 1 includes the semiconductor layer 11 including the pixels 10 and transistors to be described below, and the wiring structure 12 including wiring lines to be connected to the transistors of the pixels 10. In addition, as illustrated in FIG. 2, the second substrate 2 includes the semiconductor layer 23 including the row scanning circuit 20, and the wiring structure 24 including a wiring line that connects the semiconductor layer 23 and the first substrate 1. The pixel 10 includes a photodiode being a photoelectric conversion element PD, and typically includes a transfer transistor TX, a selection transistor SEL, a reset transistor RES, and an amplifying transistor AMP.

The pixel 10 may include a gate capacitance GATEC and a capacitance addition transistor FDINC that can increase the capacitance of a floating diffusion (FD).

In the semiconductor layer 11, the pixels 10 are arranged. The pixel 10 includes four photoelectric conversion elements PD1A to PD2B and four transfer transistors TX1A to TX2B, and the four photoelectric conversion elements PD1A to PD2B are connected to one amplifying transistor AMP. The configuration is not limited to this, and one photoelectric conversion element PD in the pixel 10 may be connected to one amplifying transistor AMP. In addition, one amplifying transistor AMP and two selection transistors SEL1 and SEL2 are connected, but one amplifying transistor AMP may be connected to one selection transistor SEL. Alternatively, a plurality of amplifying transistors AMP with gate electrodes connected to a common node may be connected to one selection transistor SEL.

A source voltage SVDD is supplied to the reset transistor RES and the amplifying transistor AMP. A plurality of vertical output lines may be arranged for one pixel column. For example, the selection transistor SEL1 may be connected to a certain vertical output line of the plurality of vertical output lines, and the selection transistor SEL2 may be connected to a vertical output line different from the vertical output line to which the selection transistor SEL1 is connected. It can be said that the amplifying transistor AMP is electrically connected to a vertical output line via the selection transistors SEL1 and SEL2.

Signals PTX1A to PTX2B are supplied to the gate electrodes of the transfer transistors TX1A to TX2B from the row scanning circuit 20 of the semiconductor layer 23 via a wiring line of the wiring structure 24 and a wiring line of the wiring structure 12. In FIG. 2, signal lines via which the signals PTX1A to PTX2B are supplied are collectively illustrated as one signal line, but the signal line may be divided in such a manner that the signals PTX1A to PTX2B are supplied to the respective transistors TX1A to TX2B via the respective signal lines. A signal PRES is supplied to a gate electrode of the reset transistor RES from the row scanning circuit 20 of the semiconductor layer 23 via a wiring line of the wiring structure 24 or a wiring line of the wiring structure 12. A signal PFDINC is supplied to a gate electrode of the capacitance addition transistor FDINC from the row scanning circuit 20 of the semiconductor layer 23 via a wiring line of the wiring structure 24 or a wiring line of the wiring structure 12. Signals PSEL1 and PSEL2 are supplied to gate electrodes of the selection transistors SEL1 and SEL2 from the row scanning circuit 20 of the semiconductor layer 23 via a wiring line of the wiring structure 24 or a wiring line of the wiring structure 12. In FIG. 2, signal lines via which the signals PSEL1 and PSEL2 are supplied are collectively illustrated, but the signal line is not limited to this.

For example, a signal line via which the signal PSEL1 is supplied may be connected to the selection transistor SEL1, and a signal line via which the signal PSEL2 is supplied, the signal line being a signal line different from the signal line via which the signal PSEL1 is supplied may be connected to the selection transistor SEL2.

Potentials DVDD and DGND are supplied to the row scanning circuit 20. Hereinafter, when signal levels of signals are described, the signal level of a signal with a relatively-high voltage will be described as High (Hi), and the signal level of a signal with a relatively-low voltage will be described as Low (Lo). In a case where matters common to the signals PTX1A to PTX2B will be described, these signals will be sometimes collectively described as signals PTX. In a case where matters common to the signals PSEL1 and PSEL2 will be described, these signals will be sometimes collectively described as signals PSEL.

The signal level of the signal PRES may have two values including Hi and Lo, or may have three or more values. In FIG. 2, the potential of the signal PRES is adjusted based on a signal output from the row scanning circuit 20, and at least any one potential selected from a potential DVDDH, a potential VRESH, a potential SGND, a potential VPRESL, and a potential VPRESL2. The signal potential of the signal PTX is controlled based on a signal output from the row scanning circuit 20, and potentials VTXH and VTXL, and the signal PTX controls on/off of the transfer transistor. The signal potential of the signal PSEL is controlled based on a signal output from the row scanning circuit 20, and potentials DVDDH and potential VSELL, and the signal PSEL controls on/off of the selection transistor.

As illustrated in FIG. 2, in the present exemplary embodiment, diodes constituting protection elements 18A and 18B are arranged in the semiconductor layer 11 included in the first substrate 1. The protection element 18A is connected to a gate electrode of the transfer transistor, and connected to a wiring line through which the signals PTX1A to PTX2B pass. A diode constituting the protection element 18A has one node connected to a wiring line through which the signal PTX passes, and the other node connected to the potential SVDD. In the present exemplary embodiment, a cathode of the protection element 18A is connected to a source line through which the potential SVDD is supplied, and an anode of the protection element 18A is connected to a wiring line through which the signal PTX passes. The protection element 18A is in a state in which a reverse bias voltage is applied.

The protection element 18B is connected to the gate electrodes of the selection transistors SEL1 and SEL2, and connected to a wiring line through which the signals PSEL1 and PSEL2 pass. A diode constituting the protection element 18B has one node connected to a wiring line through which the signal PSEL passes, and the other node connected to the potential SVDD. In the present exemplary embodiment, a cathode of the protection element 18B is connected to a source line through which the potential SVDD is supplied, and an anode of the protection element 18B is connected to a wiring line through which the signal PSEL passes. The protection element 18B is in a state in which a reverse bias voltage is applied.

In this manner, by arranging the protection elements 18A and 18B in the semiconductor layer 11, and connecting the protection elements 18A and 18B to the wiring line connected to the gate electrode of the transistor included in the pixel 10, it becomes possible to reduce malfunction or manufacturing failure of the photoelectric conversion apparatus, which will be described in detail below.

In FIG. 2, two protection elements, the protection elements 18A and 18B are connected to a wiring line in one pixel 10. The configuration is not limited to this, and one protection element may be arranged and connected to a wiring line connected to a gate electrode of a transistor included in the pixel 10. For example, a configuration in which only the protection element 18A connected to a wiring line connected to a gate electrode of the transfer transistor is arranged, and the protection element 18B is not arranged may be employed. Alternatively, the protection elements may be connected to wiring lines through which the signals PRES and signal PFDINC pass. The number of protection elements and connection relationship between protection elements and wiring lines can be appropriately changed in accordance with required reliability and required layout flexibility of the photoelectric conversion apparatus.

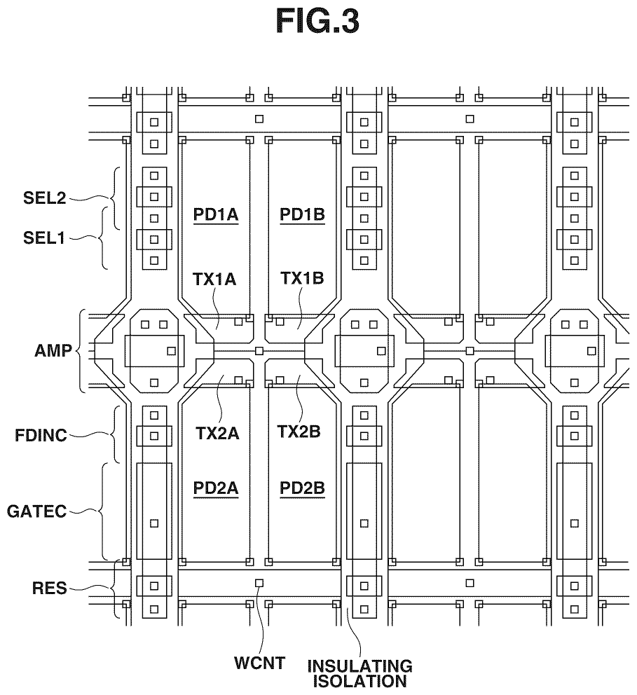

FIG. 3 is a schematic plan view illustrating a pixel of the photoelectric conversion apparatus according to the present exemplary embodiment. The four photoelectric conversion elements PD1A to PD2B share one floating diffusion region. In addition, in a column direction, a photoelectric conversion element of a certain pixel and a photoelectric conversion element of a neighboring pixel are arranged in the same active region. A well contact WCNT is arranged between a photoelectric conversion element of a certain pixel and a photoelectric conversion element of a neighboring pixel.

Because the gate electrodes of the transfer transistors TX1A to TX2B are arranged along the amplifying transistor AMP, the gate electrodes each has a bent portion, and the bent portion serves as a corner portion. In a case where the gate electrode has a bent corner portion in this manner, in a process of forming a wiring line included in the wiring structure 12, an electric field easily concentrates on the corner portion. Thus, there is a possibility that leak easily occurs in a gate insulator film. In such a case, by connecting a protection element, it becomes possible to prevent the occurrence of leak in the gate insulator film.

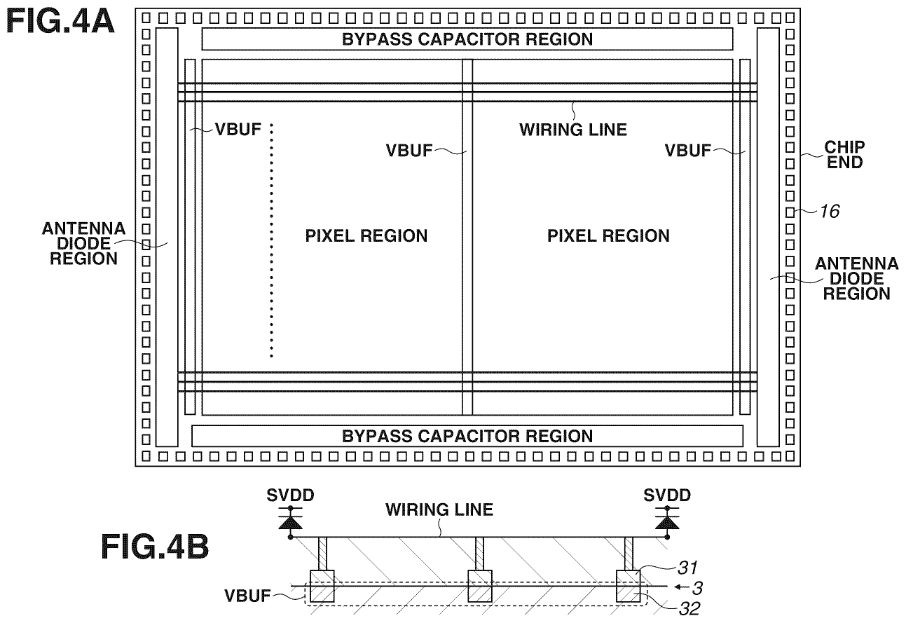

FIGS. 4A and 4B are a schematic top view and a schematic cross-sectional view illustrating the photoelectric conversion apparatus according to the present exemplary embodiment.

FIG. 4A illustrates a pixel region in a planar view that is viewed from a light incidence surface of the semiconductor layer 11, a chip end being an end of the semiconductor layer 11, a pad portion 16 in which a pad electrically connected to the semiconductor layer 23 is arranged, and a bypass capacitor region arranged between the pixel region and the pad portion 16. In the pad portion 16, a signal from the outside of the photoelectric conversion apparatus is received, or a signal is transmitted to the outside. The pixel region can include an effective pixel, an optical black (OB) pixel, and a test pixel as described below. In the bypass capacitor region, a bypass capacitor for preventing a fluctuation in source voltage is arranged. In a planar view, the pad portion 16 is arranged between the pixel region and the chip end. In addition, in FIG. 4A, an antenna diode region in which a plurality of antenna diodes serving as a protection element are arranged is arranged between the pixel region and the pad portion 16. In addition, FIG. 4A illustrates buffer circuits for supplying signals from the semiconductor layer 23 to the transistors illustrated in FIG. 2 that are arranged on the left and right of the pixel region and at the center of the pixel region.

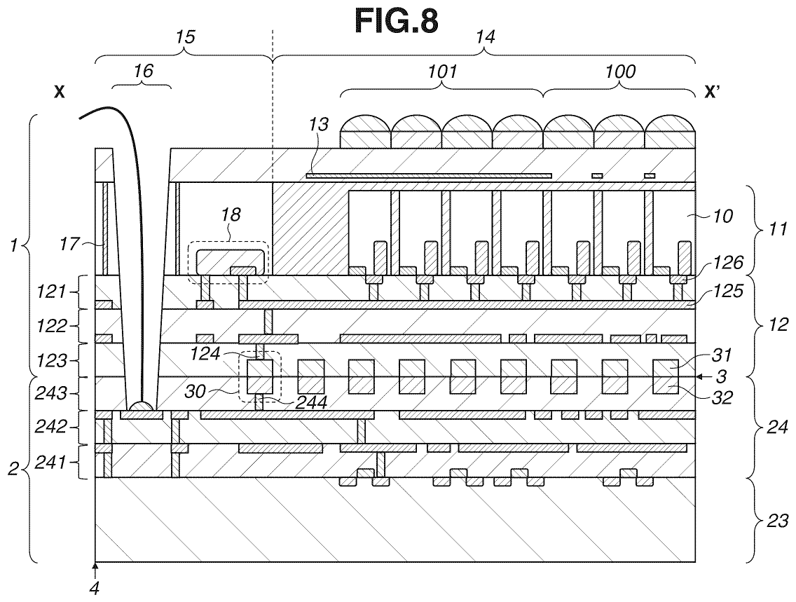

As illustrated in FIG. 4B, an antenna diode serving as a protection element is connected to a wiring line (first wiring line) that is connected to a gate electrode of a transistor in the pixel 10 and connected to the protection element. The wiring line in FIG. 4B is, for example, a wiring line through which the signal PTX passes, or a wiring line through which the signal PSEL passes. The details of wiring lines 31 and 32 illustrated in FIG. 4B will be described in detail below with reference to FIG. 8.

In FIG. 4B, in a planar view, a wiring line connected to the protection element is arranged in such a manner as to overlap two or more pixels in a row direction. Specifically, in the row direction, the wiring line extends from one end to the other end of the pixel region. The arrangement of the wiring line and the protection element is not limited to this.

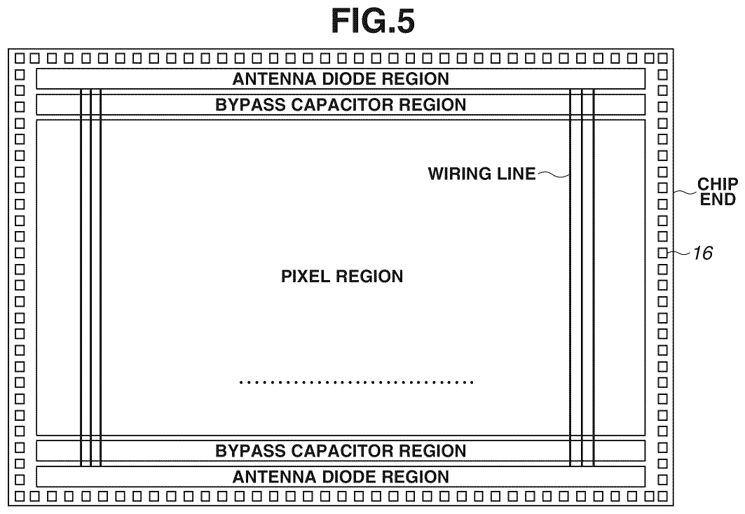

For example, as illustrated in FIG. 5, in the column direction, the pad portion 16, the antenna diode region, the bypass capacitor region, the pixel region, the bypass capacitor region, the antenna diode region, and the pad portion 16 may be arranged in order. Then, in a planar view, a wiring line connected to the protection element may be arranged in such a manner as to overlap two or more pixels in the column direction.

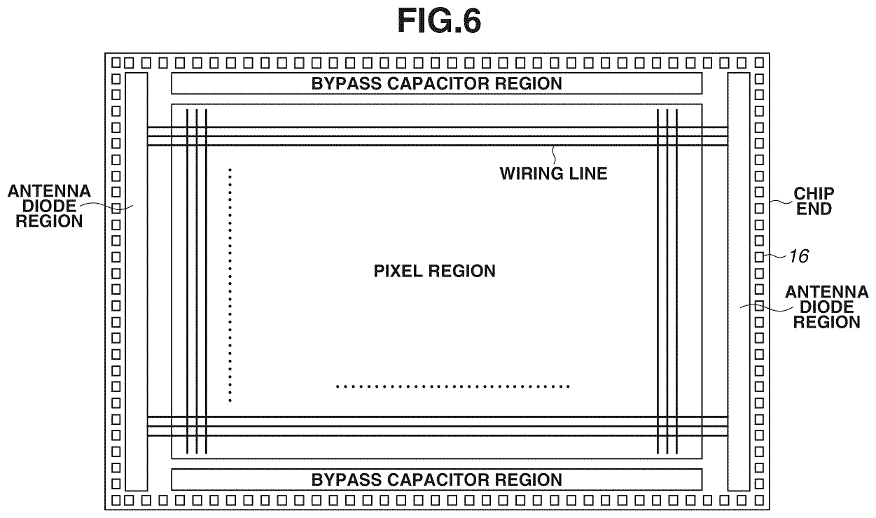

As illustrated in FIG. 6, the antenna diode regions and the like may be arranged similarly to FIGS. 4A and 4B, and a wiring line connected to the protection element may be arranged in such a manner as to overlap two or more pixels in the row direction and the column direction.

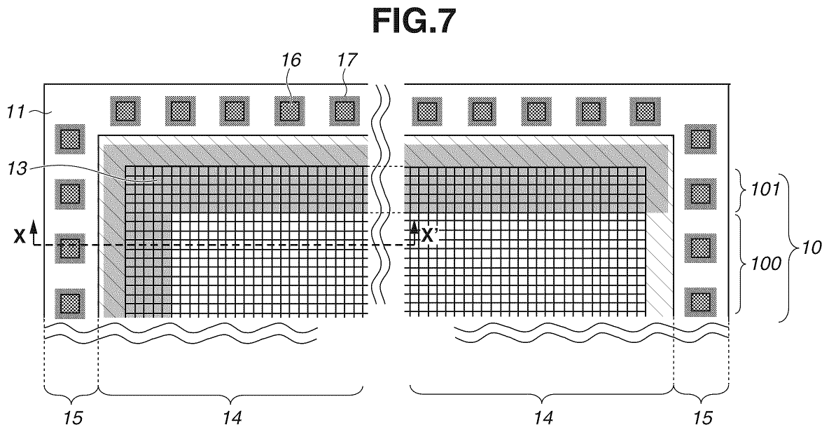

FIG. 7 is a schematic plan view of the semiconductor layer 11 that illustrates a pad portion and a pixel region of the photoelectric conversion apparatus according to the present exemplary embodiment.

In the semiconductor layer 11, in the pixels 10 arranged in a matrix, an effective pixel region 100 for capturing an image, and an OB region 101 for detecting a reference value of a black level are provided. The OB region 101 is arranged around the effective pixel region 100, and a light shielding layer 13 that shields light entering the photoelectric conversion element is provided. The pixels 10 are formed in a well region 14. In the well region 14, a bypass capacitor for preventing a fluctuation in source voltage may be arranged in a region on an outer side of the pixels 10. In the semiconductor layer 11, a region other than the well region 14 is a substrate region 15. The pad portion 16 for outputting and inputting electric signals is provided at the end of the semiconductor layer 11. An isolation region 17 is arranged around the pad portion 16. The isolation region 17 is an element isolation region in which an insulating film such as a silicon oxide film or a silicon nitride film is buried in a trench formed in the semiconductor layer 11.

FIG. 8 illustrates a cross-section taken along an X-X′ line in FIG. 7. The first substrate 1 and the second substrate 2 are stacked with being bonded on a stack surface 3. The wiring structure 12 of the first substrate 1 and the wiring structure 24 of the second substrate 2 are positioned between the semiconductor layer 11 of the first substrate 1 and the semiconductor layer 23 of the second substrate 2. The first substrate 1 includes a color filter and a microlens.

The wiring structure 12 includes M-layered wiring layers 121 (first wiring layer), 122 (second wiring layer), and 123. The wiring layers 121, 122, and 123 can be copper (Cu) wiring layers. In FIG. 8, the wiring layer 123 includes the wiring line 31 (second wiring line). The wiring line 31 is buried in a recess portion formed in an interlayer insulation film, and has a damascene structure.

The wiring structure 24 includes N-layered wiring layers 241, 242, and 243. The wiring layers 241, 242, and 243 can be Cu wiring layers. In FIG. 8, the wiring layer 243 includes the wiring line 32 (third wiring line). The wiring line 32 is buried in a recess portion formed in an interlayer insulation film, and has a damascene structure.

A metal bonding portion 30 is formed by bonding the wiring lines 31 and the wiring line 32, and the wiring lines 31 and 32 are bonded. The interlayer insulation film having the recess portion in which the wiring line 31 is buried, and the interlayer insulation film having the recess portion in which the wiring line 32 is buried are bonded (in contact).

Here, a contact plug 124 formed in the interlayer insulation film of the wiring layer 123 conducts electricity between the wiring line 31 and a wiring line included in the wiring layer 122. A contact plug 244 formed in the interlayer insulation film of the wiring layer 243 conducts electricity between the wiring line 32 and a wiring line included in the wiring layer 242. The contact plugs 124 and 244 are arranged in the metal bonding portion 30, and establish electric connection between wiring lines of upper and lower wiring layers.

The pad portion 16 includes a trench penetrating through the first substrate 1 and the wiring layer 243. In addition, the pad portion 16 includes a wiring line of the wiring layer 242 formed on the second substrate 2, and has a wire bonding structure in which a bonding wire and a bonding pad both formed of metal such as gold are connected to the wiring line. The wiring line of the wiring layer 242 can be an aluminium (Al) wiring line. It is not necessary for all the wiring lines of the wiring layer 242 to be Al wiring lines. For example, a wiring line (pad) of the pad portion 16 may be formed of Al, and other wiring lines of the wiring layer 242 may be formed of Cu.

Here, an example of wire bonding has been described, but a through via (through silicon via (TSV)) in which a trench is filled with metal may be employed. In addition, in the pad portion 16, a trench may be formed at a depth at which the trench does not penetrate through the first substrate 1, and electricity may be conducted by a bonding wire and a bonding pad. For example, the trench may stop in the middle of the semiconductor layer 11, or the trench may be formed up to a wiring line of a wiring layer included in the wiring structure 12, and electricity may be conducted by a bonding wire and a bonding pad. In such a case, by arranging a contact plug between a plurality of wiring layers, and achieving electric conduction between wiring lines by the contact plug, it becomes possible to achieve electric conduction with a wiring layer included in the second substrate 2, and the semiconductor layer 23.

A wiring line 125 (first wiring line) extending in the row direction of the pixel (direction extending along a pixel row) is arranged in the wiring layer 121. The wiring line 125 may extend in the column direction (direction extending along a pixel column), may extend in the row direction, or may both have a portion extending in the row direction and a portion extending in the column direction. The wiring line 125 is connected to a plurality of gate electrodes 126. The gate electrodes 126 can be gate electrodes of the transfer transistor, the selection transistor, the reset transistor, and the capacitive element. The wiring line 125 establishes electric connection with the second substrate 2 via the metal bonding portion 30. Signals for driving the pixel that is generated by the second substrate 2, and fixed voltage are accordingly supplied to the wiring line 125.

In the present exemplary embodiment, the second substrate 2 and the wiring line 125 are electrically connected via the metal bonding portion 30, but electric conduction is not limited to this. Electric conduction may be achieved by connecting a wiring layer of the first substrate 1 and a wiring layer of the second substrate 2 via a through via (TSV) in which a trench is filled with metal.

The protection element 18 is also connected to the wiring line 125. The protection element 18 is arranged between chip end portion 4 and the pixel 10. In addition, the protection element 18 may be arranged between the pad portion 16 and the pixel 10. In a case where a bypass capacitor is arranged in a region of the well region 14 that is on the outside side of the pixel 10, the protection element 18 may be arranged between the pad portion 16 and the bypass capacitor.

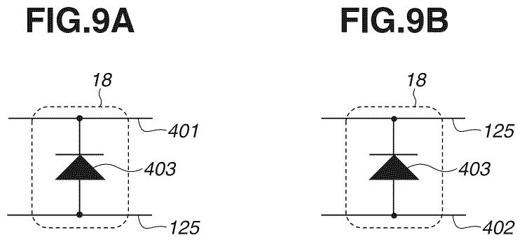

FIGS. 9A and 9B each illustrate an example of a circuit configuration of the protection element 18.

In FIG. 9A, the wiring line 125 is connected to an anode of a diode 403, and a source line 401 is connected to a cathode of the diode 403. In a case where the wiring line 125 is operated by a voltage equal to or smaller than a voltage of the source line 401, the diode 403 is always in a reverse bias state.

In FIG. 9B, the wiring line 125 is connected to the cathode of the diode 403, and a grounding line 402 is connected to an anode of the diode 403. In a case where the wiring line 125 is operated by a voltage equal to or larger than a voltage of the grounding line 402, the diode 403 is always in a reverse bias state. With this configuration, operation influence on an imaging apparatus that is to be exerted by providing the protection element 18 for the wiring line 125 becomes almost ignorable.

In the present exemplary embodiment, the protection element 18 is connected to the wiring line 125 to which the plurality of gate electrode 126 is connected. With this configuration, it is possible to flow charges generated in the wiring line 125 when the wiring line 125 is formed and when the wiring layers 122 and 123 being layers above the wiring line 125 are formed (e.g., at the time of plasma etching), to the substrate via the wiring line 125 and the protection element 18. Consequently, it is possible to suppress deterioration of a gate insulator film that is caused by a charge-up of a gate electrode, and reduce malfunction or manufacturing failure of the photoelectric conversion apparatus.

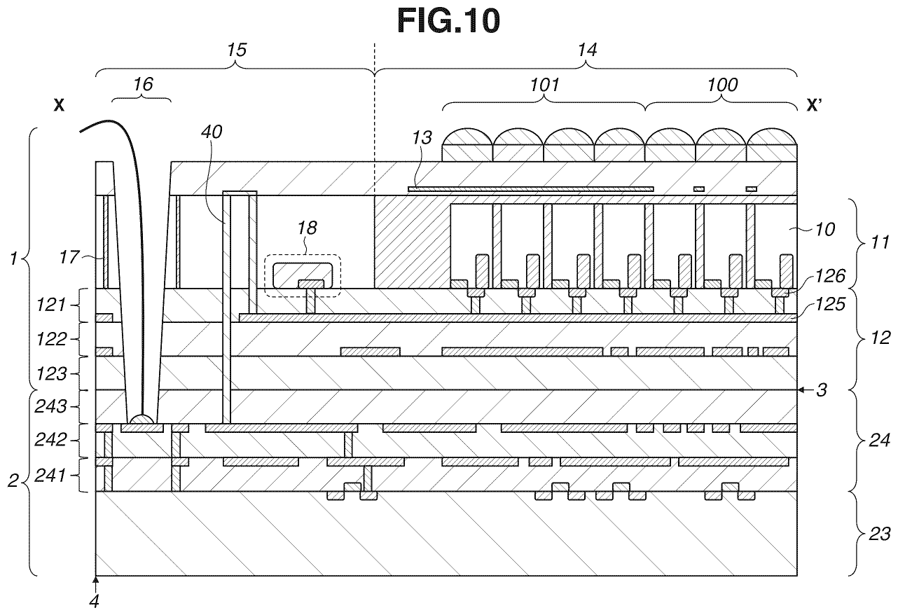

FIG. 10 is a schematic cross-sectional view of a photoelectric conversion apparatus according to a second exemplary embodiment. The position of a cross-section in FIG. 10 is the same as the position of the cross-section taken along the X-X′ line in FIG. 7.

The present exemplary embodiment differs from the first exemplary embodiment in that the metal bonding portion 30 is not provided, and electric conduction between the first substrate 1 and the second substrate 2 is ensured via a through via 40. Because parts other than this point and points to be described below have substantially the same configurations as those in the first exemplary embodiment, the description will be sometimes omitted.

In the present exemplary embodiment, the wiring line 125 and the protection element 18 are connected to the through via 40. With this configuration, it is possible to flow charges generated in the wiring line 125 when the through via 40 is formed (e.g., at the time of plasma etching), to the semiconductor layer 11 via the wiring line 125 and the protection element 18.

Consequently, it becomes possible to suppress deterioration of a gate insulator film that is caused by a charge-up of a gate electrode, and decrease a malfunction rate of the photoelectric conversion apparatus.

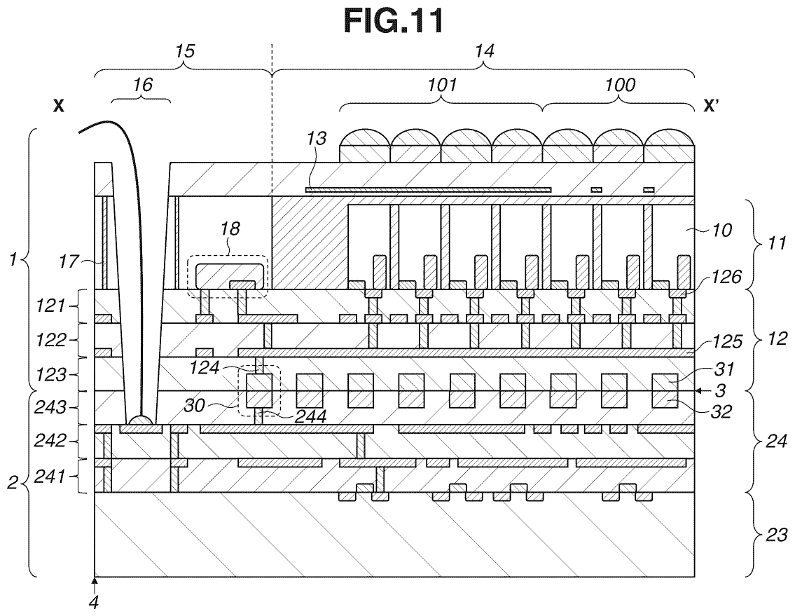

FIG. 11 is a schematic cross-sectional view of a photoelectric conversion apparatus according to a third exemplary embodiment. The position of a cross-section in FIG. 11 is the same as the position of the cross-section taken along the X-X′ line in FIG. 7.

The configuration in FIG. 11 differs from the first exemplary embodiment in that the wiring line 125 is not formed in the wiring layer 121 closest to the semiconductor layer 11, but in the wiring layer 122. Because parts other than this point and points to be described below have substantially the same configurations as those in the first exemplary embodiment, the description will be sometimes omitted.

The wiring line 125 is connected to a plurality of gate electrodes 126 via the wiring layer 122 and the wiring layer 121 therebelow. In addition, the protection element 18 is also connected to the wiring line 125 via the wiring layer 122 and the wiring layer 121 therebelow.

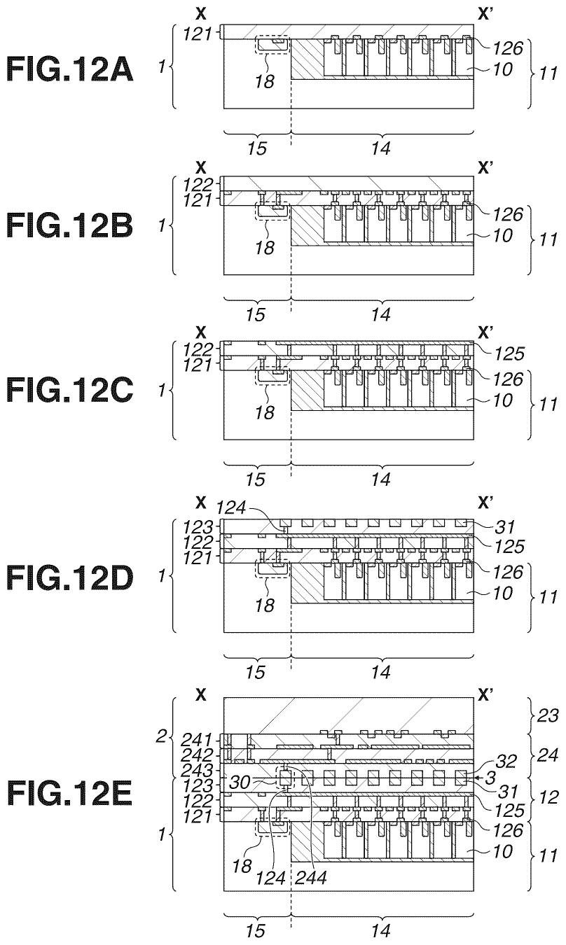

FIGS. 12A to 12E illustrate a manufacturing method of a photoelectric conversion apparatus according to the present exemplary embodiment.

First of all, as illustrated in FIG. 12A, the semiconductor layer 11 is prepared, and a well and a photodiode are formed by a known method. In addition, the surface of the semiconductor layer 11 is thermally-oxidized, and after a gate oxide film made of SiO₂ is formed, a polysilicon film is deposited on a gate insulator film. The gate electrodes 126 are formed on the polysilicon film by a photolithography process, an etching process, and a photoresist film removal process. After that, an interlayer insulation film of the wiring layer 121 included in the wiring structure 12 is deposited.

Next, as illustrated in FIG. 12B, a wiring line of the wiring layer 121 is formed. After a trench is formed on the interlayer insulation film by performing the photolithography process and an etching process that uses plasma, a metal film is deposited on the interlayer insulation film. The wiring line of the wiring layer 121 is formed by further performing a planarization process. After that, an interlayer insulation film of the wiring layer 122 is deposited.

Next, as illustrated in FIG. 12C, a wiring line of the wiring layer 122 is formed. After a trench is formed on the interlayer insulation film by performing the photolithography process and an etching process that uses plasma, a metal film is deposited on the interlayer insulation film. The wiring line of the wiring layer 122 is formed by further performing a planarization process. At this time, the wiring line 125 is in a state of being connected to the protection element 18. After that, the interlayer insulation film of the wiring layer 122 is deposited.

In FIGS. 12B to 12C, the processes have been described using an example case where Cu wiring lines are used. For example, in a case where Al wiring lines are used, first of all, an Al film is deposited, and then, after the photolithography process, the etching process that uses plasma, and the photoresist film removal process, the interlayer insulation film is deposited and planarization is performed.

Next, as illustrated in FIG. 12D, a wiring line of the wiring layer 123 is formed. After a trench is formed on the interlayer insulation film by performing the photolithography process and an etching process that uses plasma, a metal film is deposited on the interlayer insulation film. The wiring line of the wiring layer 123 is formed by further performing a planarization process.

Next, as illustrated in 12E, the first substrate 1 and the second substrate 2 are bonded. The wiring line 31 and the wiring line 32 are accordingly bonded, and it becomes possible to establish electric connection between the first substrate 1 and the second substrate 2.

Then, after planarization processing (chemical mechanical polishing (CMP)) is performed on the semiconductor layer 11, by forming a color filter layer, a microlens, and the pad portion 16 by a known method, a photoelectric conversion apparatus as illustrated in FIG. 11 is completed. The color filter layer and the microlens can be omitted depending on required characteristics of the photoelectric conversion apparatus.

In the present exemplary embodiment, the protection element 18 is connected to the wiring line 125 to which a plurality of gate electrodes 126 is connected. With this configuration, it is possible to flow charges generated in the wiring line 125 when the wiring line 125 is formed and when the wiring layer 123 above the wiring line 125 is formed (e.g., at the time of plasma etching), to the substrate via the wiring line 125 and the protection element 18. Consequently, it is possible to suppress deterioration of a gate insulator film that is caused by a charge-up of a gate electrode, and reduce malfunction or manufacturing failure of the photoelectric conversion apparatus. Because it becomes unnecessary to arrange the wiring line 125 in the lowermost wiring layer 121, a freedom degree of a wiring layer to be arranged improves, and layout efficiency of wiring layers improves.

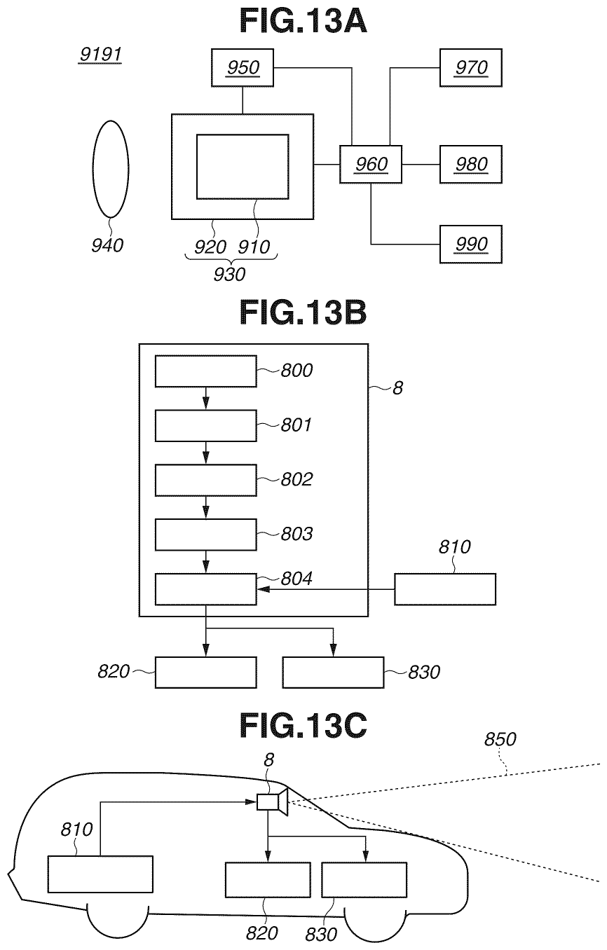

A fourth exemplary embodiment can be applied to any of the first to third exemplary embodiments. FIG. 13A is a schematic diagram illustrating a device 9191 including a semiconductor apparatus 930 according to the present exemplary embodiment. As the semiconductor apparatus 930, the photoelectric conversion apparatus according to each of the above-described exemplary embodiments can be used. The device 9191 including the semiconductor apparatus 930 will be described in detail. The semiconductor apparatus 930 can include a semiconductor device 910. Aside from the semiconductor device 910, the semiconductor apparatus 930 can include a package 920 storing the semiconductor device 910. The package 920 can include a base member on which the semiconductor device 910 is fixed, and a lid member such as glass facing the semiconductor device 910. The package 920 can further include a bonding member such as a bonding wire or a bump that connects a terminal provided in the base member and a terminal provided in the semiconductor device 910.

The device 9191 can include at least any of an optical device 940, a control device 950, a processing device 960, a display device 970, a storage device 980, and a mechanical device 990. The optical device 940 corresponds to the semiconductor apparatus 930. The optical device 940 is a lens, a shutter, or a mirror, for example, and includes an optical system for guiding light to the semiconductor apparatus 930. The control device 950 controls the semiconductor apparatus 930. The control device 950 is a semiconductor apparatus such as an application specific integrated circuit (ASIC), for example.

The processing device 960 processes a signal output from the semiconductor apparatus 930. The processing device 960 is a semiconductor apparatus such as a CPU or an ASIC for forming an analog front end (AFE) or a digital front end (DFE). The display device 970 is an electroluminescent (EL) display device or a liquid crystal display device that displays information (image) obtained in the semiconductor apparatus 930. The storage device 980 is a magnetic device or a semiconductor device that stores information (image) obtained in the semiconductor apparatus 930. The storage device 980 is a volatile memory such as a static RAM (SRAM) or a dynamic RAM (DRAM), or a nonvolatile memory such as a flash memory or a hard disk drive.

The mechanical device 990 includes a moving unit or a propulsion unit such as a motor or an engine. In the device 9191, a signal output from the semiconductor apparatus 930 is displayed on the display device 970, and transmitted to the outside by a communication device (not illustrated) included in the device 9191. For this reason, the device 9191 desirably further includes the storage device 980 and the processing device 960 aside from a storage circuit and a calculation circuit included in the semiconductor apparatus 930. The mechanical device 990 may be controlled based on a signal output from the semiconductor apparatus 930.

In addition, the device 9191 is suitable for an electronic device such as an information terminal having an image capturing function (e.g., smartphone or wearable terminal) or a camera (e.g., interchangeable lens camera, compact camera, video camera, or monitoring camera). The mechanical device 990 in a camera can drive the component of the optical device 940 for zooming, focusing, or a shutter operation. Alternatively, the mechanical device 990 in a camera can move the semiconductor apparatus 930 for an image stabilization operation.

In addition, the device 9191 can be a transport device such as a vehicle, a ship, or an airplane. The mechanical device 990 in a transport device can be used as a moving device. The device 9191 serving as a transport device is suitable for a device that transports the semiconductor apparatus 930, or a device that aids and/or automates driving (steering) using an image capturing function. The processing device 960 for aiding and/or automating driving (steering) can perform processing for operating the mechanical device 990 serving as a moving device, based on information obtained in the semiconductor apparatus 930. Alternatively, the device 9191 may be a medical device such as an endoscope, a measuring device such as a distance measuring sensor, an analytical device such as an electronic microscope, an office device such as a copier, or an industrial device such as a robot.

According to the above-described exemplary embodiment, it becomes possible to obtain good pixel characteristics. Accordingly, it is possible to enhance the value of the semiconductor apparatus. The enhancement of the value corresponds to at least any of the addition of a function, performance improvement, characteristic improvement, reliability improvement, manufacturing yield ratio improvement, environmental burden reduction, cost reduction, downsizing, and weight saving.

Accordingly, if the semiconductor apparatus 930 according to the present exemplary embodiment is used in the device 9191, the value of the device 9191 can also be enhanced. For example, by mounting the semiconductor apparatus 930 on a transport device, it is possible to obtain superior performance when capturing an image of the outside of the transport device or measuring an external environment. Thus, determining to mount the semiconductor apparatus according to the present exemplary embodiment on a transport device when manufacturing and selling the transport device is advantageous in improving the performance of the transport device itself. The semiconductor apparatus 930 is suitable especially for a transport device that performs drive assist and/or automatic operation of the transport device using information obtained in the semiconductor apparatus.

A photoelectric conversion system and a movable body according to the present exemplary embodiment will be described with reference to FIGS. 13B and 13C.

FIG. 13B illustrates an example of a photoelectric conversion system related to an in-vehicle camera. A photoelectric conversion system 8 includes a photoelectric conversion apparatus 800. The photoelectric conversion apparatus 800 is the photoelectric conversion apparatus (imaging apparatus) according to any of the above-described exemplary embodiments. The photoelectric conversion system 8 includes an image processing unit 801 that performs image processing on a plurality of pieces of image data acquired by the photoelectric conversion apparatus 800, and a parallax acquisition unit 802 that calculates a parallax (phase difference between parallax images) from the plurality of pieces of image data acquired by the photoelectric conversion system 8. Here, the photoelectric conversion system 8 may include an optical system (not illustrated) such as a lens, a shutter, or a mirror, for example, that guides light to the photoelectric conversion apparatus 800. In addition, a plurality of photoelectric conversion units approximately conjugate with a pupil of the optical system may be arranged in a pixel included in photoelectric conversion apparatus 800. For example, the plurality of photoelectric conversion units approximately conjugate with the pupil are arranged in such a manner as to correspond to one microlens. By the plurality of photoelectric conversion units receiving light beams having passed through mutually-different positions of the pupil of the optical system, the photoelectric conversion apparatus 800 outputs image data corresponding to the light beams having passed through the different positions. Then, the parallax acquisition unit 802 may calculate a parallax using the output image data. In addition, the photoelectric conversion system 8 includes a distance acquisition unit 803 that calculates a distance to a target object based on the calculated parallax, and a collision determination unit 804 that determines whether collision is likely to occur, based on the calculated distance. In this example, the parallax acquisition unit 802 and the distance acquisition unit 803 serve as an example of a distance information acquisition unit that acquires distance information regarding a distance to a target object. More specifically, the distance information is information regarding a parallax, a defocus amount, and a distance to a target object. The collision determination unit 804 may determine collision likelihood using any of these pieces of distance information. The distance information may be acquired using a Time Of Flight (ToF). The distance information acquisition unit may be implemented by dedicatedly-designed hardware, or may be implemented by a software module. Alternatively, the distance information acquisition unit may be implemented by a field programmable gate array (FPGA) or an ASIC, or may be implemented by the combination of these.

The photoelectric conversion system 8 is connected to a vehicle information acquisition apparatus 810, and can acquire vehicle information such as a vehicle speed, a yaw rate, or a rudder angle. In addition, an electronic control unit (ECU) 820 is connected to the photoelectric conversion system 8. The ECU 820 serves as a control apparatus that outputs a control signal for generating braking force, to a vehicle based on a determination result obtained by the collision determination unit 804. The photoelectric conversion system 8 is also connected to an alarm apparatus 830 that raises an alarm to a driver based on a determination result obtained by the collision determination unit 804. For example, in a case where the determination result obtained by the collision determination unit 804 indicates high collision likelihood, the ECU 820 performs vehicle control for avoiding collision or reducing damages by braking, releasing an accelerator, or suppressing engine output. The alarm apparatus 830 issues an alarm to a user by sounding an alarm, displaying warning information on a screen of a car navigation system, or vibrating a seatbelt or a steering wheel.

In the present exemplary embodiment, the photoelectric conversion system 8 captures an image of the periphery of the vehicle such as the front side or the rear side, for example.

FIG. 13C illustrates the photoelectric conversion system 8 for capturing an image of a vehicle front side (imaging range 850). The vehicle information acquisition apparatus 810 issues an instruction to the photoelectric conversion system 8 or the photoelectric conversion apparatus 800. With this configuration, the accuracy of distance measurement can be further enhanced.

The above description has been given of an example in which control is performed in such a manner as not to collide with another vehicle. The photoelectric conversion system 8 can also be applied to the control for performing automatic operation by following another vehicle, or the control for performing automatic operation in such a manner as not to deviate from a lane. Furthermore, the photoelectric conversion system 8 can be applied to a movable body (moving device) such as a vessel, an aircraft, or an industrial robot, for example, aside from a vehicle such as an automobile. This movable body includes either one or both of a drive force generation unit that generates drive force to be mainly used for the movement of the movable body, and a rotator to be mainly used for the movement of the movable body. The drive force generation unit can be an engine, a motor, or the like. The rotator can be a tire, a wheel, a screw of a ship, a propeller, or the like. Moreover, the photoelectric conversion system can be applied to a device that extensively uses object recognition, such as an intelligent transport system (ITS), in addition to a movable body.

### Modified Example

The present disclosure is not limited to the above-described exemplary embodiments, and various modifications can be made.

For example, an example in which a partial configuration of any of the exemplary embodiments is added to another exemplary embodiment, and an example in which the partial configuration is replaced with a partial configuration of another exemplary embodiment are also included in the exemplary embodiments of the present disclosure.

The device described in the above-described fourth exemplary embodiment indicates a photoelectric conversion system example to which the photoelectric conversion apparatus is applicable, and the device and the photoelectric conversion system to which the photoelectric conversion apparatus of the present disclosure is applicable is not limited to the configurations illustrated in FIGS. 13A to 13C.

The above-described exemplary embodiments merely indicate specific examples in carrying out the present disclosure, and the technical scope of the present disclosure is not to be construed in a limited manner based on these exemplary embodiments. That is, the present disclosure can be executed in various forms without departing from the technical idea thereof or major features thereof.

The exemplary embodiments described above can be appropriately changed without departing from the technical idea. The disclosure in this specification is not limited to matters described in this specification, and includes all matters that can be identified from this specification and the drawings accompanying this specification. The disclosure in this specification includes a complementary set of individual concepts described in this specification. More specifically, if “A is larger than B” is described in this specification, even if the description “A is not larger than B” is omitted, this specification is assumed to disclose that “A is not larger than B”. This is because, in a case where “A is larger than B” is described, a case where “A is not larger than B” is assumed to be considered.

The present disclosure is directed to providing a photoelectric conversion apparatus advantageous in reducing a deterioration of a gate insulator film and reducing malfunction or manufacturing failure.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-123118, filed Jul. 30, 2024, which is hereby incorporated by reference herein in its entirety.

What is claimed is:

1. A photoelectric conversion apparatus comprising:
a first semiconductor substrate including a pixel including a photoelectric conversion element and a transistor;
a first wiring structure;
a second wiring structure; and
a second semiconductor substrate configured to generate a signal to be applied to a gate electrode of the transistor and supply the signal to the transistor, the first semiconductor substrate, the first wiring structure, the second wiring structure, and the second semiconductor substrate being stacked in this order,
wherein the first semiconductor substrate includes a protection element and a plurality of the pixels arranged in a row direction and a column direction,
wherein the signal is supplied from the second semiconductor substrate to the gate electrode of the transistor,
wherein the first wiring structure includes a first wiring line extending in at least one of the row direction and the column direction in such a manner as to overlap two or more pixels in a planar view, the signal passing through the first wiring line,
wherein the first wiring line and the protection element are connected, and
wherein a reverse bias voltage is applied to a diode constituting the protection element.

2. A photoelectric conversion apparatus comprising:
a first semiconductor substrate including a pixel including a photoelectric conversion element and a transistor, the first semiconductor substrate being stacked on a second semiconductor substrate, the first semiconductor substrate including a protection element and a plurality of the pixels arranged in a row direction and a column direction; and
a first wiring structure including a first wiring line extending in at least one of the row direction and the column direction in such a manner as to overlap two or more pixels in a planar view, a signal to be applied to a gate electrode of the transistor passing through the first wiring line,
wherein the first wiring line and the protection element are connected,
wherein the first wiring line and the gate electrode of the transistor are connected, and
wherein a reverse bias voltage is applied to a diode constituting the protection element.

3. The photoelectric conversion apparatus according to claim 1,
wherein the first wiring structure includes a second wiring line arranged in a layer different from the first wiring line,
wherein the second wiring structure includes a third wiring line, and
wherein the second semiconductor substrate and the transistor are electrically connected via a metal bonding portion in which the second wiring line and the third wiring line are bonded.

4. The photoelectric conversion apparatus according to claim 3,
wherein the first wiring structure includes a plurality of wiring layers including a first wiring layer and a second wiring layer in order from a side of the first semiconductor substrate, and
wherein the first wiring line is arranged in at least one of the first wiring layer and the second wiring layer.

5. The photoelectric conversion apparatus according to claim 1, wherein, in a planar view viewed from a direction parallel to a principal surface of the first semiconductor substrate, the protection element is arranged between an end portion of the first semiconductor substrate and the photoelectric conversion element.

6. The photoelectric conversion apparatus according to claim 5, further comprising a pad portion to be electrically connected to the second semiconductor substrate,
wherein, in the planar view, the protection element is arranged between the pad portion and the photoelectric conversion element.

7. The photoelectric conversion apparatus according to claim 5, further comprising a pad portion to be electrically connected to the second semiconductor substrate,
wherein, in the planar view, the protection element is arranged between the pad portion and a bypass capacitor region.

8. The photoelectric conversion apparatus according to claim 1, wherein the protection element is connected between the first wiring line and a source voltage in a state in which a reverse bias voltage is applied.

9. The photoelectric conversion apparatus according to claim 1,
wherein the pixel includes a transfer transistor and a reset transistor, and
wherein the protection element is connected to a gate electrode of the transfer transistor, and is not connected to a gate electrode of the reset transistor.

10. The photoelectric conversion apparatus according to claim 1,
wherein the second semiconductor substrate includes a row scanning circuit and a column scanning circuit, and
wherein, in a planar view, the row scanning circuit and the column scanning circuit are arranged in such a manner that a longer direction of the row scanning circuit and a longer direction of the column scanning circuit are orthogonal to each other.

11. A device comprising:
the photoelectric conversion apparatus according to claim 1,
wherein at least any of the following is further included:
an optical device adapted to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus; and
a mechanical device configured to operate based on information obtained by the photoelectric conversion apparatus.

12. A manufacturing method of a photoelectric conversion apparatus, the manufacturing method comprising:
preparing a first substrate in which a first semiconductor substrate and a first wiring structure are stacked in this order;
preparing a second substrate in which a second wiring structure and a second semiconductor substrate are stacked in this order; and
bonding the first substrate and the second substrate in such a manner that the first wiring structure and the second wiring structure face each other,
wherein the preparing the first substrate includes
preparing a first semiconductor substrate including a protection element, and a plurality of pixels each including a photoelectric conversion element and a transistor that are arranged in a row direction and a column direction, and
forming a first wiring line that is included in the first wiring structure and extends in at least one of the row direction and the column direction, in such a manner that the protection element and the first wiring line, and a gate electrode of the transistor and the first wiring line are connected, and
wherein, in the bonding, the first wiring structure and the second wiring structure are bonded in such a manner that a wiring line included in the first wiring structure and a wiring line included in the second structure are bonded, and an interlayer insulation film included in the first wiring structure and an interlayer insulation film included in the second wiring structure come into contact with each other.

13. The manufacturing method of a photoelectric conversion apparatus according to claim 12, wherein the forming the first wiring line includes forming the first wiring line in such a manner as to simultaneously connect the protection element and the first wiring line, and the gate electrode of the transistor and the first wiring line.

14. The manufacturing method of a photoelectric conversion apparatus according to claim 13, further comprising plasma etching for forming a wiring line to be connected to the first wiring line, after the forming the first wiring line.
